(19) United States
(12) Patent Application Publication
(10) Pub. No.: US 2013/0285147 A1
(43) Pub. Date: Oct. 31, 2013

(54) COMPACT TID HARDENING NMOS DEVICE AND FABRICATION PROCESS

(71) Applicant: Fethi Dhaoui, Mountain House, CA (US)

(72) Inventor: Fethi Dhaoui, Mountain House, CA (US)

(21) Appl. No.: 13/870,860

(22) Filed: Apr. 25, 2013

Related U.S. Application Data
(60) Provisional application No. 61/637,946, filed on Apr. 25, 2012.

(51) Int. Cl. H01L 29/78; H01L 29/66

(52) U.S. Cl. CPC H01L 29/78; H01L 29/66477
USPC 257/368; 438/296

(57) ABSTRACT

A radiation-hardened transistor is formed in a p-type semiconductor body having an active region doped to a first level and surrounded by a dielectric filled shallow trench isolation region. N-type source/drain regions are disposed in the active region and spaced apart to define a channel. A gate is disposed above the channel, and is self-aligned with the source/drain regions. First and second p-type regions are disposed in the p-type semiconductor body on either side of one of the source/drain regions and are doped to a second level higher than the first doping level. The first and second p-type regions are self aligned with and extend outwardly from a first side edge of the gate. The ends of the gate extend past the first and second p-type regions.

### CROSS-REFERENCE TO RELATED APPLICATIONS

The present application claims the priority benefit of U.S. provisional application No. 61/637,946 filed Apr. 25, 2012 and entitled “Compact TID Hardening NMOS Device and Fabrication Process,” the disclosure of which is incorporated herein by reference.

### BACKGROUND

1. Field of the Invention

The present invention relates to semiconductor technology, and specifically to MOS technology. More particularly, the present invention relates to radiation hardened MOS transistors and to methods for fabricating such transistors.

2. The Prior Art

The present invention is intended to solve the problem of transistor off-state leakage in n-channel MOS (NMOS) high-voltage (HV) transistors due to ionizing radiation. Ionizing radiation over time deposits positive charge in the insulating materials surrounding the transistor, causing NMOS devices to exhibit large parasitic drain-to-source leakages along the now inverted transistor sidewalls. These large leakage currents limit the usable lifetime of NMOS transistors in radiation environments. Due to the lower body doping of HV transistors, these devices are especially vulnerable to this failure mechanism.

Total Ionizing Dose (TID) is a long-term degradation of electronics due to the cumulative energy deposited in a material. Typical effects include parametric failures, or degradations in device parameters such as increased leakage current, threshold voltage shifts, or functional failures. Major sources of TID exposure in the space environment include trapped electrons, trapped protons, and solar protons, as well as trapped charge in dielectrics caused by X-Rays and Gamma Rays and high-energy ions.

There is several transistor degradation modes caused as a result of ionization dose. One is a shift in threshold voltage Vₜ. The Vₜ of NMOS and PMOS devices shift in a negative direction due to hole trapping in the gate oxide. Another is sidewall leakage.

The Vₜ of parasitic isolation sidewall transistors also shifts in a negative direction. For NMOS transistors, as Vₜ becomes more negative, sidewall leakage increases exponentially as the parasitic transistor starts to turn on at a lower threshold voltage. This is the primary lifetime limitation for standard medium voltage (MV) and high-voltage (HV) NMOS devices. Shallow-trench isolation (STI) accumulates positive charge during irradiation. The positive charge turns on parasitic sidewall transistors at the STI edges, forming an uncontrolled conducting path from drain to source.

FIGS. 1A through 1C illustrate the effects of TID on a typical linear NMOS STI isolated transistor. FIG. 1A is an isometric view of the structure, FIG. 1B is a cross-sectional view of the left-most portion of the structure taken through the drain, and FIG. 1C is a side view of the edge of the structure at the inner boundary of the STI isolation trench. Positive charge built up in the STI oxide (shown as multiple “+” signs in FIGS. 1A and 1B) lowers the threshold of the transistor, causing leakage current to flow from the drain to source along the edge of the structure through a parasitic transistor that exists at the gate edge proximate to the STI boundary as shown by arrow 10 in FIGS. 1A and 1C.

Existing prior-art layout solutions to this problem include transistors formed using annular gate geometries in which there are no isolation sidewalls connecting the drain and source nodes, because the gate completely encircles the drain of the transistor.

FIGS. 2A and 2B are top and cross sectional views of an annular-gate transistor and illustrate an example layout of an existing annular-gate solution to the ionizing radiation problem for fabricating HV NMOS devices. The annular-gate transistor is fabricated within a boundary defined by a shallow trench isolation (STI) structure comprising a shallow trench filled with an insulating material such as a deposited silicon dioxide. An annular polysilicon gate is formed and defined in the center of the transistor region defined by the STI structure. An annular source region and a square-shaped drain region are then implanted by a self-aligned-gate process using the annular gate as an implant mask as is known in the art. The source comprises the region outside of the gate abutting the inner perimeter of the STI structure and the drain is formed through an aperture in the center of the gate.

As may be seen from an examination of FIGS. 2A and 2B, there is no drain edge at the inner STI periphery, since the annular source completely occupies the edge of the transistor structure. While this prevents the existence of a parasitic transistor at the gate edge at the STI region, since there is no gate edge at this location in the transistor, this solution to the problem is not entirely satisfactory.

It is difficult to scale width and length for transistor design in such structures. For example, SPICE models cannot easily be used to determine effective widths and lengths of such devices. Curved and circular structures are not provided for in conventional simulation software to model transistors. In addition, as geometries shrink, the right-angle edges of the structures in the annular gate transistor become disallowed in design rules, creating a lower limit on the size of such transistors. For example below 65 nm, design rules prohibit 90° or even 45° angles on polysilicon over diffusion.

Another prior art solution to the problem when using lateral transistors with STI isolation has been to add an additional p-type implant to the diffusion sidewall. This implant is performed after trench etch and before trench fill. This solution delays the onset of parasitic leakage, but does not eliminate it. In addition, the additional sidewall implant degrades junction breakdown, which is problematic in HV transistors.

### BRIEF DESCRIPTION

According to a first aspect of the present invention, a radiation-hard transistor is formed in a p-type semiconductor body. An active region is disposed in the p-type semiconductor body and is doped to a first level and surrounded by a dielectric filled shallow trench isolation region. First and second n-type source/drain regions are disposed in the active region and spaced apart to define a channel. A gate is disposed above and insulated from the channel. First and second ends of the gate extend past ends of the channel over the p-type semiconductor body. A first p-type region is disposed in the p-type semiconductor body and doped to a second level higher than the first doping level. The first p-type region is self aligned with and extends outwardly from a first side edge of the gate on a first side of the first source/drain region. The first end of the gate extends past the first p-type region. A second p-type region is disposed in the p-type semiconductor body and doped to the second level. The second p-type region is self aligned with and extends outwardly from the first side edge of the gate on a second side of the first source/drain region opposite the first side. The second end of the gate extends past the second p-type region.

According to another aspect of the present invention, a process for fabricating a radiation-hard transistor is disclosed. If the transistor is to be formed in a p-well, first, an implant is performed to form the p-well. The active areas are then defined by forming and filling STI regions. A gate dielectric layer is formed over the active areas. Polysilicon gates are then deposited and defined. Masking, implant and drive processes are performed to form source/drain regions. Masking, implant and drive processes are performed to form p+ regions. The customary back-end processing steps are then performed.

### BRIEF DESCRIPTION OF THE DRAWING FIGURES

FIGS. 1A through 1C are diagrams of an example layout of prior-art STI HV NMOS devices, illustrating the problems addressed by the present invention.

FIGS. 2A and 2B are diagrams of an example layout of an existing prior art annular gate transistor solution for constructing HV NMOS devices.

FIG. 3A is a top view of an example layout of an STI isolated linear HV NMOS device according to one illustrative embodiment of the present invention.

FIG. 3B is a top view of the STI isolated linear HV NMOS device of FIG. 3A, showing only the active and shallow trench isolation regions.

FIGS. 4A, 4B, and 4C are cross-sectional views of the STI isolated linear HV NMOS device shown in FIG. 3 taken through lines 4A-4A, 4B-4B, and 4C-4C, respectively, in a direction across the gate and the channel of the STI isolated linear HV NMOS device shown in FIG. 3.

FIG. 4D is across-sectional view of the STI isolated linear HV NMOS device shown in FIG. 3 taken through lines 4D-4D in a direction parallel to the gate and the underlying channel of the STI isolated linear HV NMOS device shown in FIG. 3.

FIG. 5 is a flow diagram showing an illustrative process for fabricating the STI isolated linear HV NMOS device according to one illustrative embodiment of the present invention.

FIG. 6 is a is a top view of alternate embodiments of the STI isolated linear HV NMOS device of the present invention, showing only the active and STI regions.

FIGS. 7A through 7D are cross sectional views of embodiments of the radiation-hardened transistor whose active regions and STI regions are depicted in FIG. 6.

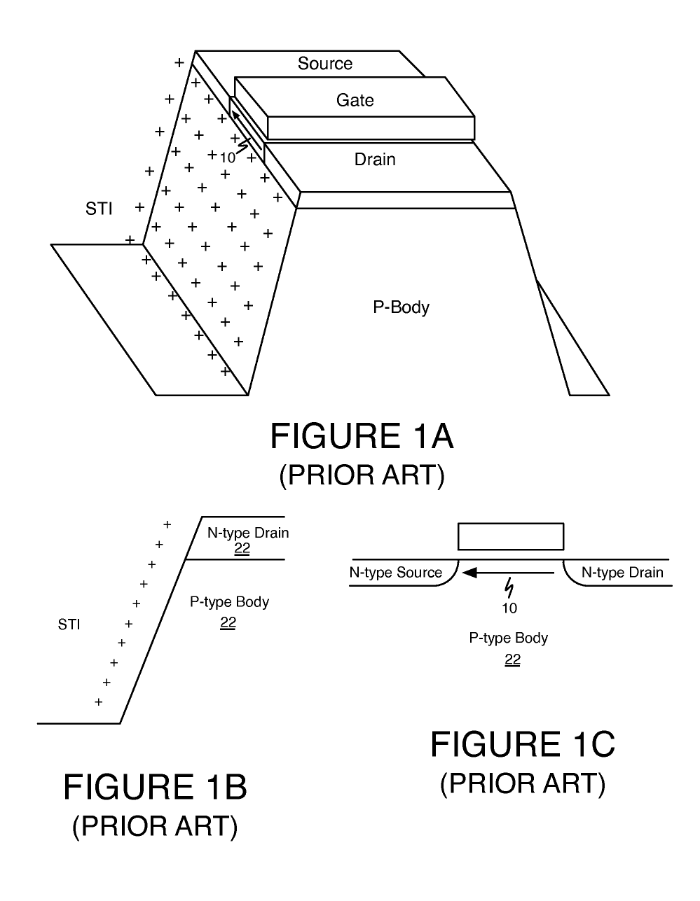

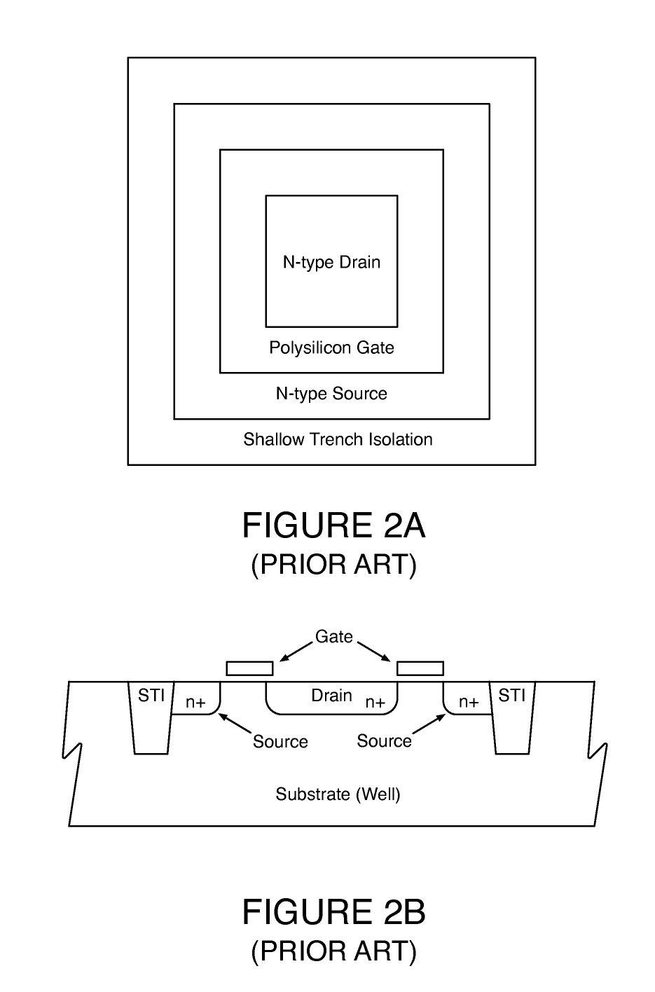

### DETAILED DESCRIPTION

Persons of ordinary skill in the art will realize that the following description of the present invention is illustrative only and not in any way limiting. Other embodiments of the invention will readily suggest themselves to such skilled persons.

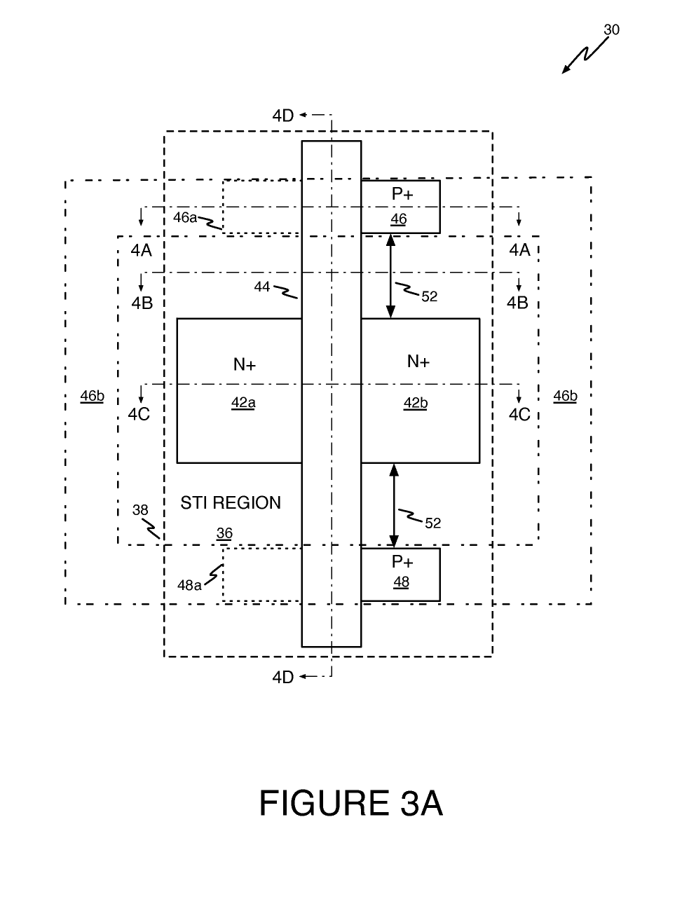

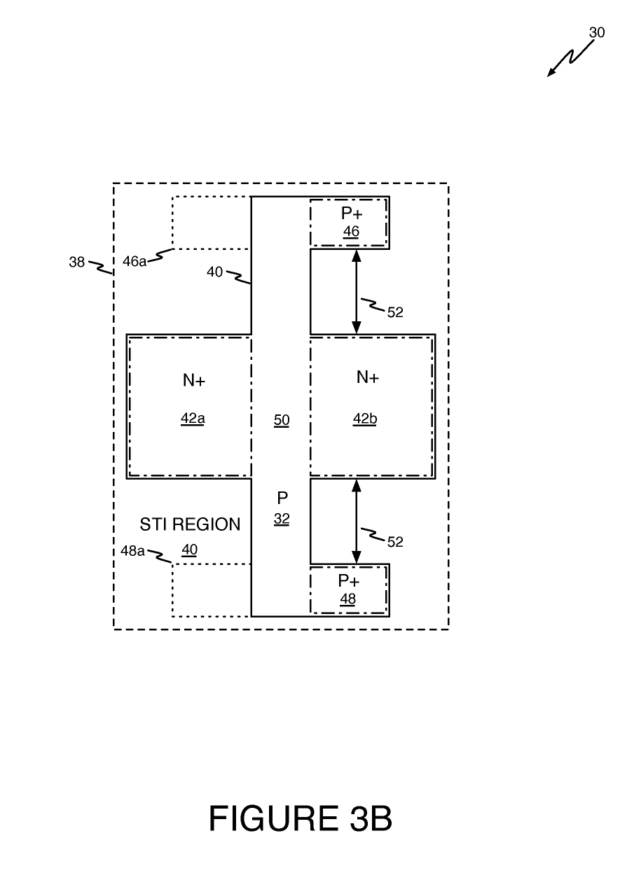

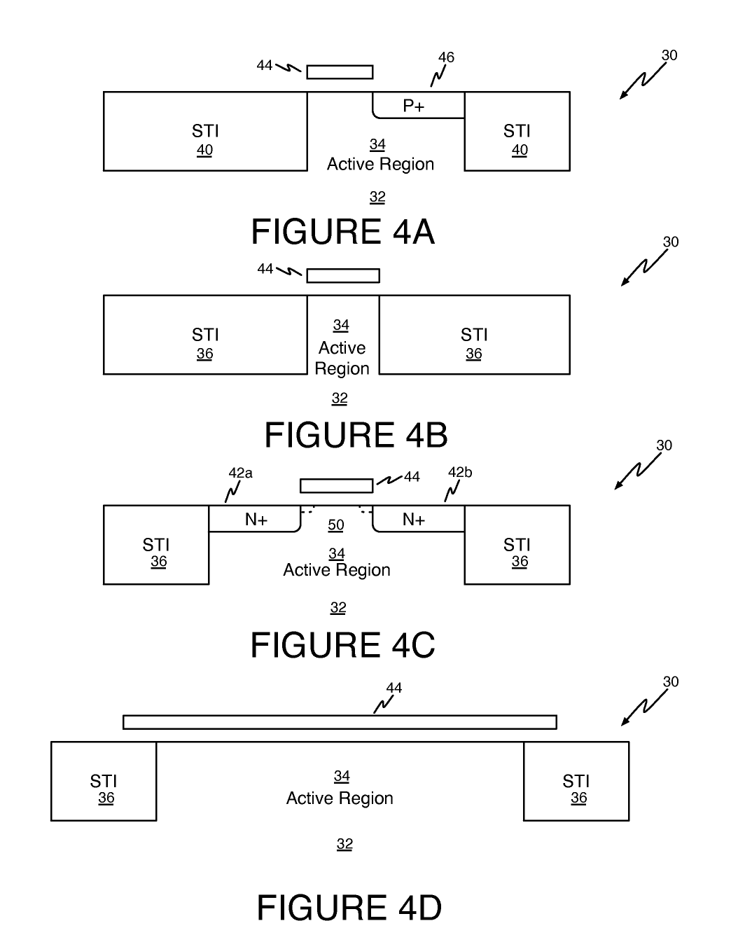

Referring now collectively to FIGS. 3A, 3B, and 4A through 4D, an illustrative embodiment of an STI isolated linear HV NMOS device 30 according to the present invention will be described.

FIG. 3A is a top view of an example layout of the STI isolated linear HV NMOS device 30. STI isolated linear HV NMOS device 30 is formed in a semiconductor body 32 (shown in FIGS. 4A through 4D), which may be a p-type semiconductor body or p-well. Semiconductor body 32 may be doped to a level of between about 10¹⁴ atoms/cm³ and about 10¹⁸ atoms/cm³, using a doping species such as boron.

An active region 34 is defined in the semiconductor body 32. Active region 34 (shown in FIGS. 4A through 4D) is bounded by a shallow trench isolation (STI) region 36. FIG. 3B is a top view of the STI isolated linear HV NMOS device 30 of FIG. 3A, showing only the active region 34 and shallow trench isolation region 36. The outer boundary of STI region 36 is shown at dashed line 38 in FIGS. 3A and 3B, and the inner boundary of STI region defining the active region 34 is indicated by a solid line 40 in FIG. 3B

Spaced-apart source/drain regions 42a and 42b are formed in the active region 34 and are shown in dashed lines in FIG. 3B. Doping levels for the source/drain regions 42a and 42b may be between about 10¹⁸ atoms/cm³ and about 10²⁰ atoms/cm³, using a doping species such as arsenic. A gate 44 (seen in FIG. 3A) is disposed above and insulated from the active region 34. In some embodiments of the invention, the gate 44 is self-aligned with the first and second n-type source/drain regions. In other embodiments of the invention, lightly-doped source drain regions (shown in dashed lines in FIG. 4C) extend from the edges of source and drain regions 42a and 42b under the gate 44 and the gate 44 may or may not be self aligned with the source and drain regions 42a and 42b.

A first p-type region 46 is disposed in the active region 34 and doped to a second level higher than the first doping level. Doping levels for the first p-type region may be between about 10¹⁸ atoms/cm³ and about 10²⁰ atoms/cm³, using a doping species such as boron. The first p-type region 46 is self aligned with the gate 44 and extends outwardly from a side edge of the gate 44 on a first side of one of the source/drain regions (illustrated as 42b in FIGS. 3A and 3B). The first end of the gate 44 extends past the edges of the channel 50 disposed between source/drain regions 42a and 42b and also extends past the outer edge of the first p-type region 46.

A second p-type region 48 is disposed in the active region 34 and doped to a second level higher than the first doping level. Doping levels for the first p-type region may be between about 10¹⁸ atoms/cm³ and about 10²⁰ atoms/cm³, using a doping species such as boron. The second p-type region 48 is self aligned with the gate 44 and extends outwardly from the side edge of the gate 44 on a second side of one of the source/drain regions (illustrated as 42b in FIGS. 3A and 3B). The second end of the gate 44 extends past the edges of the channel 50 disposed between source/drain regions 42a and 42b and also extends past the outer edge of the second p-type region 48.

Persons of ordinary skill in the art will appreciate that p-type regions 46 and 48 may be located on the other side of gate 44 as shown in dashed lines at reference numerals 46a and 48a. Such skilled persons will also appreciate that, alternately, one of regions 46 and 48 could be formed to one side of the gate 44 while the other one of regions 46 and 48 could be formed to the other side of the gate 44. In any event, the p-type regions 46 and 48 are spaced apart from source and drain region 42a and 42b by a minimum amount (shown in FIGS. 3A and 3B by dimension arrow 52) such that a lateral misalignment of gate 44 (e.g., gate shifted to the left in an embodiment such as shown in FIGS. 3A and 3B) resulting in a small unwanted finger of n-type diffusion extending in a downward direction in FIGS. 3A and 3B from the bottom left corner of region 42b in FIGS. 3A and 3B and a small finger of p-type diffusion extending in an upward direction in FIGS. 3A and 3B from the top left corner of region 48 in FIGS. 3A and 3B will not meet or come close enough to one another to degrade the voltage breakdown rating of the device. The same gate misalignment will cause unwanted diffusion fingers to be formed between region 42b and p-type region 46.

In an alternate embodiment shown in FIGS. 3A and 3B, a single diffused region 46b may be employed instead of separate regions 46, 48, 46a and 46b. Diffused region 46b is similar to a guard ring and surrounds the entire active region.

Persons of ordinary skill in the art will recognize that this design rule spacing between region 42b (or 42a) and p-type regions 46 and 48 will be different for different devices made in accordance with the present invention and will depend on such factors as device geometry, doping levels, and intended operating voltages. For example, if 20 volts is desired a spacing of 1μ may be required.

Some of the various features of the STI isolated linear HV NMOS device 30 can be better seen in the cross sectional views of FIGS. 4A, 4B, 4C, and 4D. FIGS. 4A, 4B, and 4C are cross-sectional views of the STI isolated linear HV NMOS device shown in FIG. 3A taken through lines 4A-4A, 4B-4B, and 4C-4C, respectively, in a direction across the gate 44 and the channel 50. The cross section of FIG. 4A is taken in a direction across the gate 44 through the P+ extension region 46. The cross section of FIG. 4B is taken in a direction across the gate 44 in an area between the P+ extension region 46 and the outer edges of source/drain regions 42a and 42b. The cross section of FIG. 4C is taken in a direction across the gate 44 and the channel 50 through the approximate center of the channel 50 and approximately bisects the source/drain regions 42a and 42b and channel region 50 of the device 30.

FIG. 4D is across-sectional view of the STI isolated linear HV NMOS device 30 shown in FIG. 3A taken through lines 4D-4D in a direction along the length of the gate 44 at the approximate center of the length of the channel 50 of the STI isolated linear HV NMOS device 30 shown in FIG. 3A.

The STI isolated linear HV NMOS device 30 of the present invention eliminates the field edge by extending the thin field region under the gate to the higher-level doped regions 46 and 48 of the same conductivity type as the active region 34 in the semiconductor body 32.

The STI isolated linear HV NMOS device 30 of the present invention may be fabricated using conventional CMOS processing techniques without having to modify the process. Only the masks used in the process would be altered to define the features of the present invention.

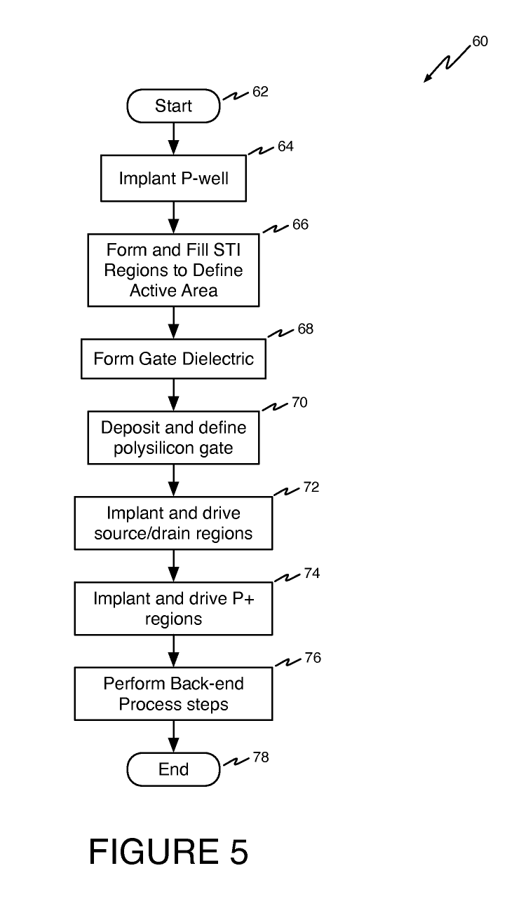

Referring now to FIG. 5, a flow diagram shows an illustrative process 60 for fabricating the STI isolated linear HV NMOS device according to one illustrative embodiment of the present invention.

The process begins at reference numeral 62. At reference numeral 64, an implant is performed to form a p-well. At reference numeral 66, the active areas are then defined by forming and filling STI regions.

At reference numeral 68, a gate dielectric layer is formed over the active areas. At reference numeral 70, polysilicon gates are then deposited and defined.

At reference numeral 72, masking, implant and drive processes are performed to form source/drain regions. At reference numeral 74, masking, implant and drive processes are performed to form p+ regions. At reference numeral 76, the customary back-end CMOS processing steps are then performed to complete the integrated circuit containing the device. The fabrication process ends at reference numeral 78.

There are several advantages provided by the present invention. Among these advantages are that the transistor of the present invention has a small layout footprint. In addition, unlike annular gate transistors the transistor of the present invention is scalable, with no limitation on device size. The features of the transistor of the present invention are self aligned, minimizing yield issues of the device caused by mask alignment errors.

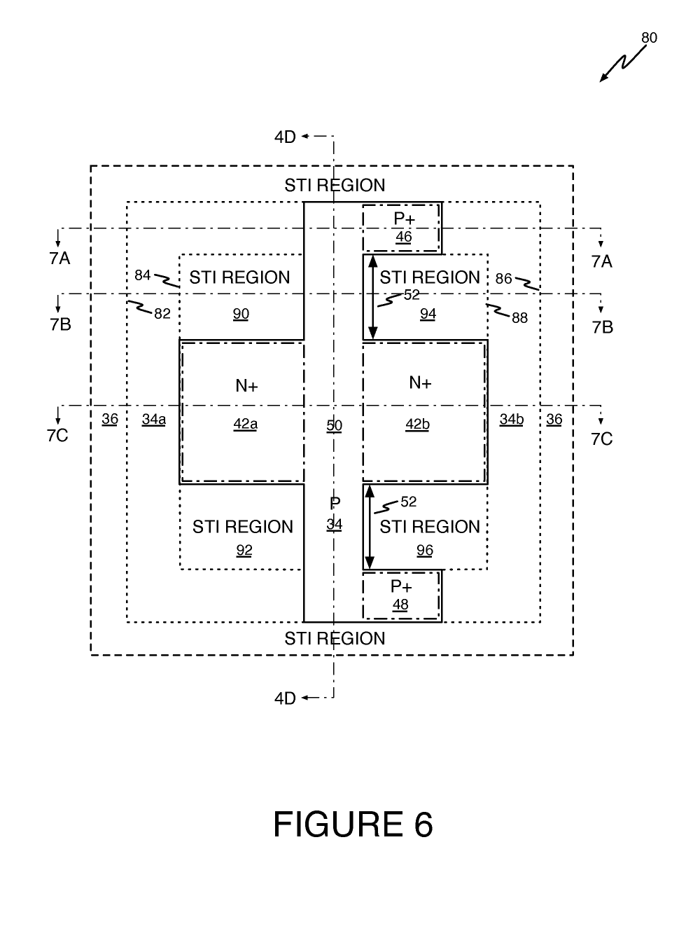

For coverage, the portion of the active region 34 that extends beyond the source/drain regions 42a and 42b may be further extended to generate a complete ring or a half a ring surrounding the source/drain regions 42a and 42b. Referring now to FIG. 6, a is a top view of the STI isolated linear HV NMOS device 80 of the present invention, showing only the active and shallow trench isolation regions, illustrates these aspects of the preset invention. Elements included in FIG. 6 that are the same as elements in FIGS. 3A and 3B are identified by the same reference numerals that are used for those elements in FIGS. 3A and 3B.

In FIG. 6, dashed lines 82 and 84 show the boundaries of the active area 32 an embodiment where the active region is extended in a half-ring depicted as active region 34a to the left of the source/drain region 42a. Dashed lines 86 and 88 show the boundaries of the active region 34 an embodiment where the active region is extended in a half-ring depicted as active region 34b to the right of the source/drain region 42a. The active region 34 can be extended by a full ring if the boundaries of the active region 34 are extended as shown by the active regions 34a and 34b enclosed by dashed line pairs 82 and 84 and 86 and 88. Additional STI regions 90, 92, 94, and 96 will be created if these embodiments of the invention are practiced. Additional STI regions 90 and 92 will be created if a left-side half ring active region 34a is employed. Additional STI regions 92 and 94 will be created if a right-side half ring active region 34b is employed. All of additional STI regions 90, 92, 94, and 96 will be created if a full ring active region including 34a and 34b is employed.

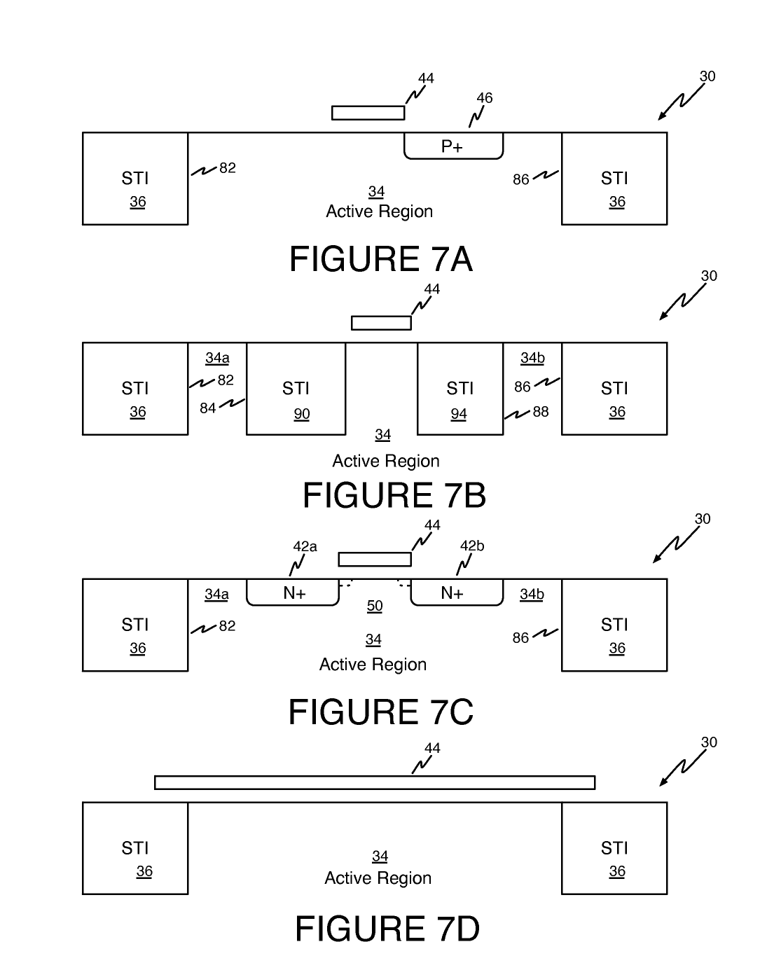

The remainder of the radiation-hardened transistor 80 of FIG. 6 is very similar to the embodiments depicted in FIGS. 3A and FIGS. 4A through 4D, except that additional active regions are present as shown in FIGS. 7A through 7D. FIGS. 7A through 7D are cross sectional views of the radiation-hardened transistor 80 whose active regions and STI regions are depicted in FIG. 6. Although gate 44 is not depicted in FIG. 6, gate 44 is disposed in the same place in the device as in the embodiment depicted in FIGS. 3A and 4A through 4D. Accordingly, gate 44 will be shown in the cross sectional views of FIGS. 7A through 7D even though that feature of the device is not depicted in FIG. 6.

The cross section of FIG. 7A is taken through lines 7A-7A in FIG. 6 in a direction across where the gate 44 would be in the device through the P+ extension region 46. The cross section of FIG. 7B is taken through lines 7B-7B in FIG. 6in a direction across where the gate 44 would be in the device in an area between the P+ extension region 46 and the outer edges of source/drain regions 42a and 42b. The cross section of FIG. 7C is taken through lines 7C-7C in FIG. 6 in a direction across where the gate 44 would be in the device and the channel 50 through the approximate center of the channel 50 and approximately bisects the source/drain regions 42a and 42b and channel region 50 of the device 30. In embodiments where lightly-doped source-drain regions are employed they will extend under the gate as is known in the art and the gate 44 and source and drain regions 42a and 42b may or may not be self aligned. Although gate 44 is not depicted in FIG. 6, it is disposed in the same place in the device as in the embodiment depicted in FIGS. 3A and 4A through 4D.

FIG. 7D is across-sectional view of the STI isolated linear HV NMOS device 30 shown in FIG. 6 taken through lines 7D-7D in a direction along the length of where the gate 44 would be in the device at the approximate center of the length of the channel 50 of the STI isolated linear HV NMOS device 6. Although gate 44 is not depicted in FIG. 6, it is disposed in the same place in the device as in the embodiment depicted in FIGS. 3A and 4A through 4D. Persons of ordinary skill in the art will observe that FIG. 7D is identical to FIG. 4D, since, in this direction, the transistor 80 is identical to the transistor 30 of FIGS. 3A and 4A through 4D.

The differences between FIGS. 4A through 4C and FIGS. 7A through 7C reflect the presence of the active area ring described with reference to FIG. 6. FIGS. 7A through 7C are drawn as if the full ring is present in the device. Persons of ordinary skill in the art will appreciate which features are omitted if transistor 80 includes only either a left-side or right-side half ring extended active region 34a or 34b. FIG. 7B includes the additional STI regions 90 and 94. If the cross section of FIG. 7B had been taken on the lower side of the transistor below the source/drain regions 42a and 42b, additional STI regions 90 and 94 would have been shown. Other differences include the increased width of active region 34 in FIG. 7A both to the right and to the left of p-type region 46. Persons of ordinary skill in the art will recognize that the design rule spacing (in the vertical direction as shown by dimension arrows 52 in FIG. 6) between either of regions 42a and 42b and regions 46 and 48 also applies in this embodiment of the invention.

As may be seen from the description herein, no process modifications are required to fabricate the radiation-hardened transistor of the present invention, meaning that it can be fabricated using existing CMOS semiconductor fabrication processes. A P+ implant and or PESD implant or any other form of p-type implant already available in the process may be used for regions 46 and 48.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

What is claimed is:

1. A radiation-hardened transistor comprising:
a p-type semiconductor body;
an active region disposed in the p-type semiconductor body doped to a first level and surrounded by a dielectric filled shallow trench isolation region;
first and second n-type source/drain regions disposed in the active region and spaced apart to define a channel therebetween;
a gate disposed above and insulated from the channel, first and second ends of the gate extending past ends of the channel over the p-type semiconductor body;
a first p-type extension region disposed in the p-type semiconductor body and doped to a second level higher than the first doping level, the first p-type extension region self aligned with and extending outwardly from a side edge of the gate on a first side of one of the source/drain regions, the first end of the gate extending past the first p-type extension region; and
a second p-type extension region disposed in the p-type semiconductor body and doped to the second level, the second p-type extension region self aligned with and extending outwardly from a side edge of the gate on a second side of one of the source/drain regions opposite the first side, the second end of the gate extending past the second p-type extension region.

2. The radiation-hardened transistor of claim 1 wherein the gate is self-aligned with the first and second n-type source/drain regions.

3. The radiation-hardened transistor of claim 1 wherein the first and second p-type regions extend outwardly from the same side edge of the gate.

4. The radiation-hardened transistor of claim 1 wherein the first and second p-type regions extend outwardly from opposite side edges of the gate.

5. The radiation-hardened transistor of claim 1 wherein the active region forms a half of a closed ring.

6. The radiation-hardened transistor of claim 1 wherein the active region forms a full closed ring.

7. A method for fabricating a radiation-hardened transistor comprising:
defining an active area in which the radiation-hardened transistor will be located;
forming a gate dielectric layer over the active area;
depositing and defining a polysilicon gate for the radiation-hardened transistor;
forming source/drain regions for the radiation-hardened transistor; and
forming p+ extension regions for the radiation-hardened transistor.

8. The method of claim 7 wherein defining the active area in which the radiation-hardened transistor will be located comprises defining the active area in a p-well formed in a semiconductor substrate.

8. The method of claim 7 wherein defining the active area in which the radiation-hardened transistor will be located comprises forming STI trenches and filling the STI trenches with a dielectric material.

10. The method of claim 7 wherein forming p+ extension regions for the radiation-hardened transistor comprises forming first and second p+ extension regions on a same side edge of the polysilicon gate.

11. The method of claim 7 wherein forming p+ extension regions for the radiation-hardened transistor comprises:
forming a first p+ extension region on a first side edge of the polysilicon gate; and
forming a second p+ extension region on a second side edge of the polysilicon gate opposite the first side edge.
